(19) United States
(12) Patent Application Publication
(10) Pub. No.: US 2013/0019460 A1
(43) Pub. Date: Jan. 24, 2013

(54) Personal Energy Memorabilia

(71) Applicant: Willard Alan Mayes, Dallas, TX (US)

(72) Inventor: Willard Alan Mayes, Dallas, TX (US)

(21) Appl. No.: 13/543,841

(22) Filed: Jul. 8, 2012

Related U.S. Application Data
(60) Provisional application No. 61/572,790, filed on Jul. 19, 2011.

(51) Int. Cl. H05K 13/00

(52) U.S. Cl. 29/592.1

(57) ABSTRACT

In a method for enhancing memorabilia, a store of energy harvested from the body of a person or animal relevant to an item of memorabilia is associated with the item. In representative embodiments, energy storage devices charged with such harvested energy are comprised in or secured with items of memorabilia or items accessory to them, where they may additionally power electronic devices.

### FIELD OF THE INVENTION

The present invention relates to the field of memorabilia. In particular, the invention is directed to a method for enhancing the intrinsic memorabilia worth of an item of memorabilia by associating with it a store of energy harvested from a person or animal related to the memorabilia. The invention also relates tangentially to methods and devices for harvesting energy from human or animal body sources.

### BACKGROUND OF THE INVENTION

In this disclosure, the term “personal energy” refers to energy naturally translated by the living body of a human being or animal, such as the thermal energy of body heat and the kinetic energy of movement.

In practice, the term “memorabilia” is used liberally to describe any item that serves as a record or reminder of a certain person(s), animal(s) and/or event(s), with the item's intrinsic worth and/or usefulness derived at least in part from its association with said person(s), animal(s) and/or event(s). Some words commonly used synonymously with memorabilia are keepsake, memento, commemorative item, token of remembrance and souvenir. While souvenirs tend to be thought of as items related to a place visited, those that mark an occasion or are associated with a significant person or animal are a type of memorabilia as well.

While the most valuable memorabilia items are associated with famous people or significant cultural or historic events, there also exists local and personal memorabilia. Within a community such as a town, a club, a local sports team, or a graduating class, for example, members create items of memorabilia that embody memories of the times and events they have shared. At a more personal level, a family photo can be an item of memorabilia, as can a toy one had as a child, a dress worn on one's wedding day, or a letter received from a dear friend. Some memorabilia items may not be related to any specific event but rather derive worth from their associations with certain, usually famous, persons and/or animals.

Historically, memorabilia were rarely intentionally created as they commonly are today with tenuous, indirect links to the event, person or animal and thus nominal memorabilia worth. The intrinsic and commercial values of mass-produced memorabilia pale in comparison to those of items that have, even for a brief instance, belonged to, been used by, or simply been in the presence of a historically or culturally significant person or animal. Such personalized items are more valuable not only because their supply is limited, but also because they are believed by many to possess a quality that mass produced memorabilia items cannot: an intangible presence of an aura of personal energy imparted upon them by the famous person or animal's touch. For those who sense or believe that this aura exists, a personalized memorabilia item is a physical embodiment of the famous one's personal energy, and having the item establishes or enhances a bond they feel with the famous person or animal.

However, since the presence of such energy is not discernible by any of the five human senses, some argue that its existence is only inferred, that the imparted energy's reality is wholly contingent upon a person's belief in it. The actual presence of the famous person or animal's energy in a personalized item of memorabilia is therefore not certain to all. This uncertainty represents a shortcoming in prior art memorabilia items, a shortcoming that could be addressed only by an improvement that would make it possible to somehow link to a memorabilia item the actual energy of the person or animal associated with it. The uncertainty could be further overcome if there were a way to experience this energy by one or more of the five human senses. The present invention teaches methods and suggests means for achieving these improvements.

An essential element of the methods disclosed herein is energy harvesting from human or animal sources. One general approach to this type of energy harvesting is to employ micro-energy harvesting devices, which harvest very small amounts of energy collected over an extended period; for example, thin-film piezoelectric and thermoelectric generator modules. Micro-energy harvesting, alternately referred to as “micro-harvesting,” is essentially a passive form of harvesting that can require little intentional effort from the subject. Furthermore, the harvesting subject can wear micro-harvesting devices without interference to their movement; thus, the thermal or kinetic energy of even athletes actively engaged in sports could be harvested at the very moments of their famous performances. Conversely, the personal energy of a weak or incapacitated person or animal could be harvested passively with a micro-harvesting device.

Another solution is the use of a manually operated mechanical electric generator, whereby a person or animal mechanically inputs and converts their muscle energy (biomechanical energy) to electrical power. While the term “energy harvesting” has come for many to refer to today's micro-energy harvesting technology, in fact some energy harvesters are large mechanisms and have been around for a very long time; windmills, for example. A manually operated mechanical electrical generator is a personal energy harvester; it captures the energy of the operator and translates the energy to useful electrical power. It can generate a vastly greater amount of electrical energy than a micro-harvesting device, and in a far shorter period of time. This could appeal as a convenience factor to some, especially those who would like to harvest a large store of energy from a human or animal source. In contrast to micro-harvesting methods, harvesting personal energy with a manually operated generator would normally require the person or animal's active participation.

### SUMMARY

It is the object of the present invention to propose methods for enhancing an item of memorabilia by associating it with a store of personal energy harvested from a person or animal who is somehow associated with the memorabilia item, said person or animal alternately sometimes referred to in this disclosure as the “subject”. Personal energy is defined for purposes of this disclosure as the energy naturally translated by the living body of a human being or animal, such as thermal or kinetic energy. The methods teach securing a store of the subject's harvested personal energy with the memorabilia item and/or using it to power an electronic device comprised in the item or its accessory. The disclosed methods overcome the shortcoming of uncertainty that exists with prior art memorabilia with regards to whether or not an item of memorabilia that is personally marked by a relevant person or animal is imbued with a residual presence of their personal energy. Representative physical embodiments of the methods are presented to make clear their inventive nature, hint at how they can be applied in practice, and to point out some aesthetic and practical considerations that may guide producers of personal energy memorabilia.

A personal energy memorabilia item is an item of memorabilia that is associated with a store of energy harvested from the living body of the person and/or animal whose link to the item causes it to have intrinsic worth as memorabilia. Intentionally created and incidental memorabilia can be or become personal energy memorabilia. In general, a personal energy memorabilia item comprises or is associated with an accessory item that comprises a space, structure and/or component that is designed hold in, on or with the memorabilia item an energy storage device that has been charged with energy harvested from the living body of the memorabilia item's human and/or animal subject(s). This harvested energy is referred to herein as “personal energy.” Personal energy memorabilia items will preferably also comprise an electronic device which is powered by this energy storage device. The electronic device, when operated, will stimulate one or more of the five human senses and thereby evince the subject's stored personal energy, overcoming any uncertainty of its presence.

Personal energy memorabilia can take any form. What will be the common distinguishing characteristic of a personal energy memorabilia item is its association with a store of personal energy harvested from the living body of one or more persons and/or animals who are somehow related to the intrinsic memorabilia worth of the memorabilia item. The memorabilia item can itself comprise an energy storage device that is charged with the person(s) and/or animal(s)' harvested personal energy; or, it can be associated in a variety of ways with another item that comprises the same. Preferably, a personal energy memorabilia item additionally comprises or is associated with another item comprising an electronic device that is powered by this energy storage device and evinces the harvested personal energy stored therein by producing an output that stimulates one or more of the human senses when so powered.

The present disclosure proposes two general approaches to harvesting and creating a store of the harvested energy that is associated with a personal energy memorabilia item. One approach teaches the use of external harvesting and charging apparatus, while a second approach teaches comprising one or both of these components in an item of personal energy memorabilia itself, in an item accessory to it, or in some combination thereof. These approaches to personal energy harvesting and the configurations of storage and evincing electronic devices are exemplified in six representative embodiments.

In a first representative embodiment a powered card in the shape of an American football and featuring design elements of a particular American football team comprises an LED that is powered by mounted thin-film batteries which have been charged with personal energy harvested from one or more of the team's players. Harvesting and charging are accomplished by means of a wristband that is outfitted with a thermoelectric generator (TEG) capable of harvesting thermal energy from a human body, converting the energy to electrical power and charging an inserted powered card. Building upon this is a second representative embodiment wherein the described powered card, previously charged with the player's harvested personal energy, is secured to a football team jersey featuring the name and team number of one of the team's players to personalize the otherwise common sports memorabilia item with the player's harvested personal energy and thereby enhancing the item's intrinsic memorabilia worth and likely, therefore, its commercial value.

In a third representative embodiment, a sports trophy comprises stacked thin-film batteries that power an electroluminescent sheet featuring a team's logo. The batteries are charged with the collective, merged personal energy individually harvested from each of the team's players.

A self-charging powered card, the fourth representative embodiment, is a concert memorabilia item that comprises its own energy harvesting device, thin-film batteries that are charged by this device with harvested personal energy, and an electronic device that evinces this energy. A concert attendee wears the powered card during a concert to capture and add to the memorabilia item their own personal energy generated during the excitement of the concert.

In a fifth representative embodiment, specialized piezoelectric generator modules harvest the collective personal energy of those attending a concert by capturing the acoustic energy of the “crowd noise” they generate during the event. This harvested collective personal energy charges thin-film batteries comprised in a memorabilia plaque specially created for the concert event and powers the plaque's electroluminescent display of the featured band's logo.

In a sixth and final representative embodiment, a newlywed couple creates a wedding keepsake by individually harvesting their personal energy throughout the day of their wedding and then combining their harvested personal energy to jointly charge thin-film batteries comprised in a personalized wedding keepsake that is illuminated by a comprised light source powered by these batteries.

Existing technology offers several ways and concomitant devices for harvesting energy from human or animal sources. It is not the purpose of the present invention to teach or disclose an energy harvesting method or device, but rather how to utilize these for the purposes of the present invention. Thus, only a brief and general review of energy harvesting is included and some preferences stated. The thermal energy of a person or animal's body heat is the preferred source of energy harvested for a personal energy memorabilia item. Human beings associate the warmth of the body with the life and spirit of a living person or animal, and sharing this warmth is a bonding experience. Present technology suggests the use of a thermoelectric generator (TEG) to harvest the thermal energy of body heat.

A single item of personal energy memorabilia can be associated with the personal energy of one or more persons and/or animals. The subject or subjects' personal energy can be harvested firsthand or secondhand. A personal energy memorabilia item can have one or more electronic devices, with one, some or all powered by the subject or subjects' harvested personal energy in a variety of arrangements.

The length of time an electrical energy storage device can retain a charge is of primary consideration for its inclusion in personal energy memorabilia. A particular thin-film battery with exceptional specifications in these regards is identified and stated as preferred herein.

### BRIEF DESCRIPTION OF THE SEVERAL DRAWINGS

FIG. 1 is a front view of a first representative embodiment of the present invention, a football-shaped celluloid plastic powered card.

FIG. 2 is a rear view of the powered card of FIG. 1.

FIGS. 3 and 4 illustrate a simplified operating circuit and component design of the powered card of FIG. 1.

FIGS. 5 and 6 illustrate a wearable charging station in the form of a wristband.

FIG. 7 schematically illustrates a simplified operating circuit of the charging station shown in FIGS. 5 and 6.

FIG. 8 illustrates the action of placing the powered card of FIG. 1 into the wearable charging station shown in FIGS. 5 and 6.

FIG. 9 illustrates a method for sealing the powered card of FIG. 1, once charged, for authentication purpose.

FIGS. 10 and 11 illustrate a second representative embodiment of the present invention wherein the powered card of FIG. 1 is attached to a memorabilia football jersey.

FIG. 12 is a front view of a third representative embodiment of the present invention, a championship trophy.

FIG. 13 is a rear view of the trophy of FIG. 12.

FIG. 14 is a perspective view of a battery pack that comprises thin-film micro-energy cell batteries.

FIG. 15 illustrates a thin-film battery structure built on a celluloid plastic card substrate.

FIG. 16 illustrates a device used to discharge a number of the thin-film battery structures of FIG. 15 simultaneously in order to charge the battery pack of FIG. 14.

FIG. 17 is a front perspective view of a fourth representative embodiment, a self-charging powered card memorabilia item.

FIG. 18 is a rear perspective view of the self-charging powered card of FIG. 17.

FIG. 19 illustrates a method for creating a fifth representative embodiment, a concert memorabilia plaque enhanced with a store of collective personal energy harvested from the acoustic energy of “crowd noise.”

FIG. 20 illustrates a method for creating a sixth representative embodiment, a wedding keepsake in the form of an illuminated cube powered by a collective store of energy individually harvested from the bride and groom on their wedding day.

FIG. 21 illustrates the typical structure of a thermoelectric generator (TEG).

FIG. 22 is a front perspective view of a self-charging thin-film battery structure built on a celluloid plastic card substrate and comprising the thermoelectric generator (TEG) of FIG. 21.

FIG. 23 is a rear perspective view of the battery structure of FIG. 22.

FIG. 24 is a perspective view of a proposed charging station designed to merge and transfer electrical energy from the battery structure of FIGS. 22 and 23 to the sixth representative embodiment wedding keepsake illuminated cube of FIG. 20.

FIG. 25 is a detailed front perspective view of the illuminated cube of FIG. 20.

### DETAILED DESCRIPTION OF THE INVENTION AND REPRESENTATIVE EMBODIMENTS

The term “memorabilia” as used herein will be understood to describe any item that serves as a record or reminder of a certain person(s), animal(s) and/or event(s), wherein the item's intrinsic worth and/or usefulness is derived at least in part from its association with said person(s), animal(s) and/or event(s). Some words commonly used synonymously with memorabilia are keepsake, memento, commemorative item, token of remembrance, and souvenir. It will be understood that the term memorabilia encompasses souvenir items when such items have memorabilia worth derived from their association with a memory of a person and/or event.

For efficiency, the pronouns “their”, “they” and “them” are sometimes used in this disclosure as gender-neutral pronouns referring to singular or plural nouns, as is common in English usage today. The term “personal energy” is used herein to refer to energy that is “produced” naturally by the living body of a human being or animal; “harvested personal energy” is such energy collected by an energy harvesting device. While the term “energy harvesting” has come for many to refer to today's cutting edge technology for micro-energy, in this disclosure the definition of “energy harvesting device” shall include a mechanical electric generator that is manually operated by a person or animal, the definition of “personal energy” above given shall encompass the energy expended thereby, and when harvested, this energy shall be understood to be “harvested personal energy.”

As used herein, the term “personalize” refers to the action of adding to an object something which facilitates the object being distinctly associated with a particular person or persons, and/or animal(s). As used herein, the term “subject” refers to the person and/or animal associated with a particular item of memorabilia, i.e. the person or animal whose association with the item causes the item to have intrinsic worth as an item of memorabilia. The terms “human being” and “person” are used alternately herein with the same meaning. The term “and/or” as used in this disclosure includes any and all combinations of one or more of the items associated or listed. The singular forms “a,” “an” and “the” are intended to include plural forms as well, unless clearly defined or indicated otherwise in the context they appear. When the terms “comprise(s),” “comprised” and/or “comprising” are used, they specify the presence of a stated component, item, feature, etc., but do not preclude the presence or addition of other features, components, items, and etcetera. Terms used in this disclosure are intended to have meanings consistent with their meanings in the context of the art and their meanings should not be contracted, expanded or construed to have different meanings or interpretations unless they are defined in such a way in this disclosure. It will be understood that different orientations are possible in addition to the orientations depicted in the figures.

The creation of a personal energy memorabilia item will generally happen in two phases: provision and personalization. A memorabilia product that is structured and outfitted to serve as a personal energy memorabilia item is provided; then, it is personalized and thus enhanced with the harvested personal energy of the memorabilia item's subject. Generally, separate parties, a provider and a user, will carry out these tasks. Likely, the provider will be a person or business that produces items that can serve as personal energy memorabilia, and the user a customer who purchases such an item from the provider, directly or indirectly, and then personalizes and thus enhances it with their own or a significant other's harvested personal energy.

The user may or may not him- or herself be the subject of the memorabilia item. In some cases, an existing item of memorabilia will be made into a personal energy memorabilia item by securing with it a store of energy harvested from a person and/or animal associated with the item and its significance. In this case, a producer will make and/or provide an energy storage device, standalone or comprised in another item, that can store the subject or subjects' harvested personal energy and can be secured in, on or with the existing memorabilia item, possibly used to power an evincing electronic device comprised therein as well. In certain circumstances, the provider could both provide an item of memorabilia and personalize it with the personal energy of the relevant person(s) and/or animal(s). For example, a provider may be tasked with creating or providing the memorabilia item, harvesting and storing energy from the subject, and adding the stored harvested energy to the item before delivering it.

The special intrinsic memorabilia worth of a personal energy memorabilia item lies with the store of personal energy it holds, uses and/or is otherwise associated with. A personal energy memorabilia item retains this special worth for as long as the store of personal energy remains. Therefore, charged shelf life, i.e. how long an energy storage device can maintain an operational charge when stored and not used, should be a fundamental consideration when selecting an energy storage device to be used with an item of personal energy memorabilia.

The preferred energy storage device for the present invention is a rechargeable micro-energy cell (MEC) type of thin-film battery produced by Infinite Power Solutions (IPS) of Littleton, Colo. in USA and marketed under the brand name THINERGY®. These batteries are designed specifically for energy harvesting applications and have an exceptional estimated charged shelf life of twenty or more years. Furthermore, they have exceptional depth of discharge (DOD) of 99% at full discharge. By fully discharging a THINERGY® MEC before recharging it with energy harvested from a person or animal subject, the MEC can, for all intents and purposes, be charged exclusively with the subject's harvested personal energy, a characteristic that would enhance even further the intrinsic worth of a personal energy memorabilia item. Hereinafter, the term “micro energy cell(s)” and the acronym “MEC” will be used in this disclosure to refer to these preferred thin-film batteries. It should be noted that micro-energy cells at their present state of development require a power management integrated circuit (PMIC). As such, a PMIC as well is part of the circuitry where needed in the representative embodiments given in this disclosure.

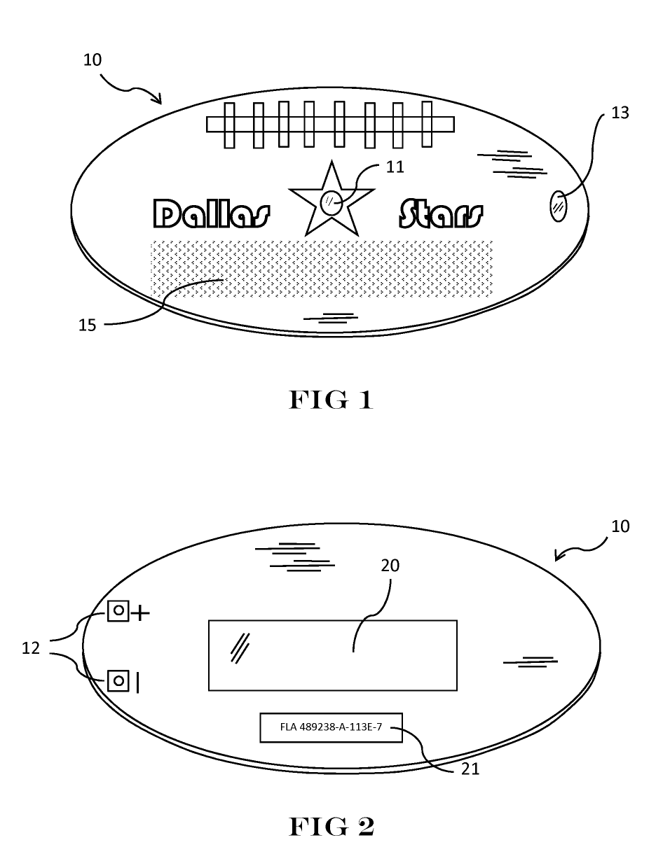

The first representative embodiment of the present invention is an American football-shaped celluloid plastic powered card 10, shown in FIGS. 1-4, that can be personalized and thus enhanced with energy harvested from the body of a football player, preferably during a game and while they are engaged in the game.

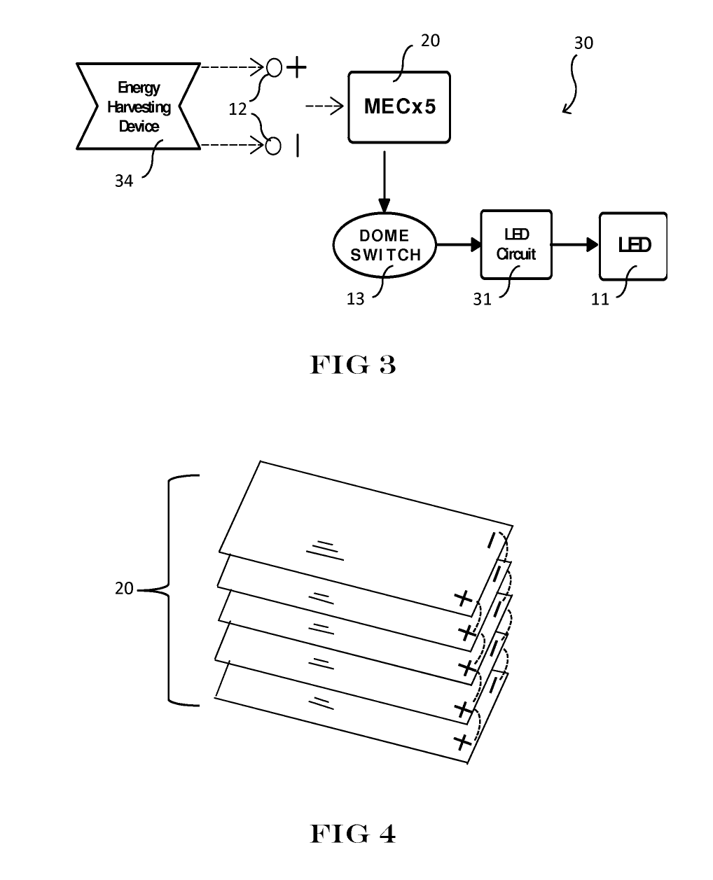

A “powered card” is a card that comprises an energy storage device and some kind of electronic feature powered by it. The powered card 10 of the first representative embodiment comprises a stack of five micro-energy cells (MEC's) 20, stacked in parallel, as illustrated in FIG. 4, and mounted on the backside of the powered card 10. The MEC's 20 power a star-shaped light emitting diode (LED) 11 disposed on the front of the powered card 10 and operated by a dome switch 13. Two contact posts 12 facilitate charging of the powered card's stacked MEC's 20 with the personal energy of the person or animal subject of the memorabilia item via any suitable harvesting method and device. A printed serial number 21 on the back of the powered card guarantees authenticity of the powered card 10 as an official team memorabilia item. An autograph block 15 allows an individual member of the team to further personalize the powered card 10 and authenticate the energy stored in it as their own harvested personal energy. A representative illustration of a simplified operating circuit 30 of the powered card 10 is shown in FIG. 3. An LED integrated circuit 31 is included in this design to allow for a dynamic display, such as blinking. The LED integrated circuit 31 would require some electrical power itself to operate, power which would come from the MEC's 20. Since the store of the subject's personal energy is essential to a personal energy memorabilia item's enhanced intrinsic memorabilia worth, the benefits of a dynamic display have to be weighed against the value of preserving the store of harvested personal energy.

The powered card 10 is not a personal energy memorabilia item until it holds a store of the subject's harvested personal energy, in this case that of a football player. Any harvesting method and its concomitant devices can be used to accomplish this charging, so long as devices are capable of harvesting energy from the living body of a person or animal and converting it to electrical power output. The powered card 10 could be charged directly, using wires from a selected harvesting apparatus and so-called “banana clips” connected to its contact posts 12. However, this would not be a practical, user-friendly solution. A charging station designed specifically for charging the powered card 10 with the electrical output of an energy harvesting device is a better solution. However, since this particular powered card 10 embodiment is intended to harvest energy from an athlete while they are engaged in playing football, the energy harvesting device and the charging station need to be wearable and of designs that do not interfere with the player's performance.

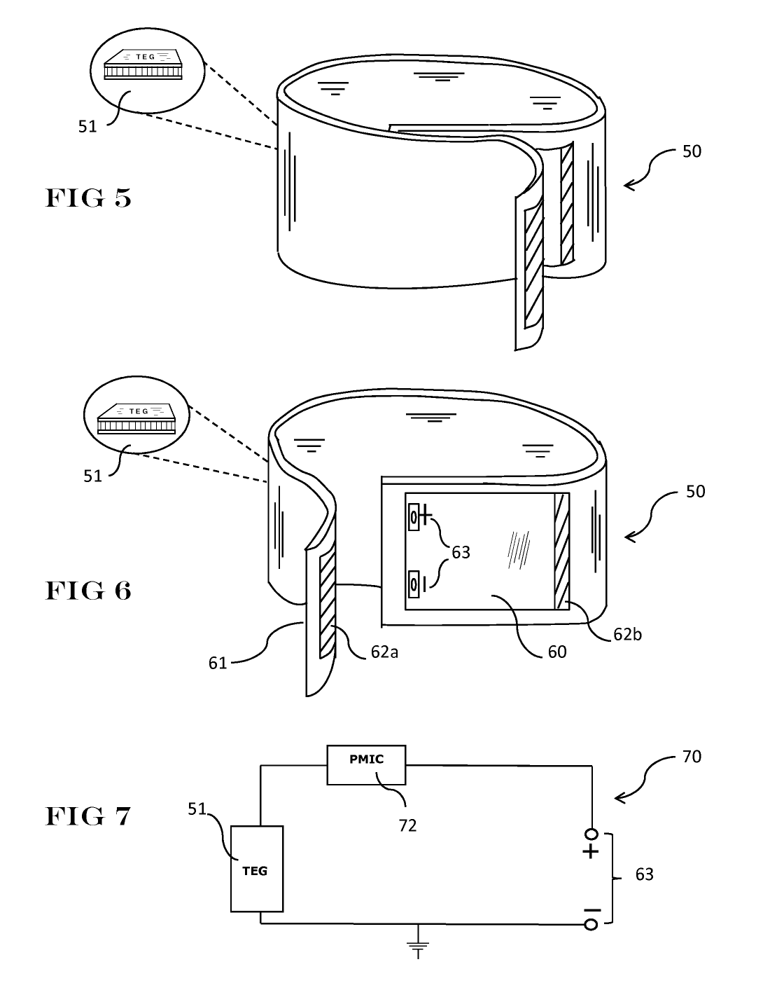

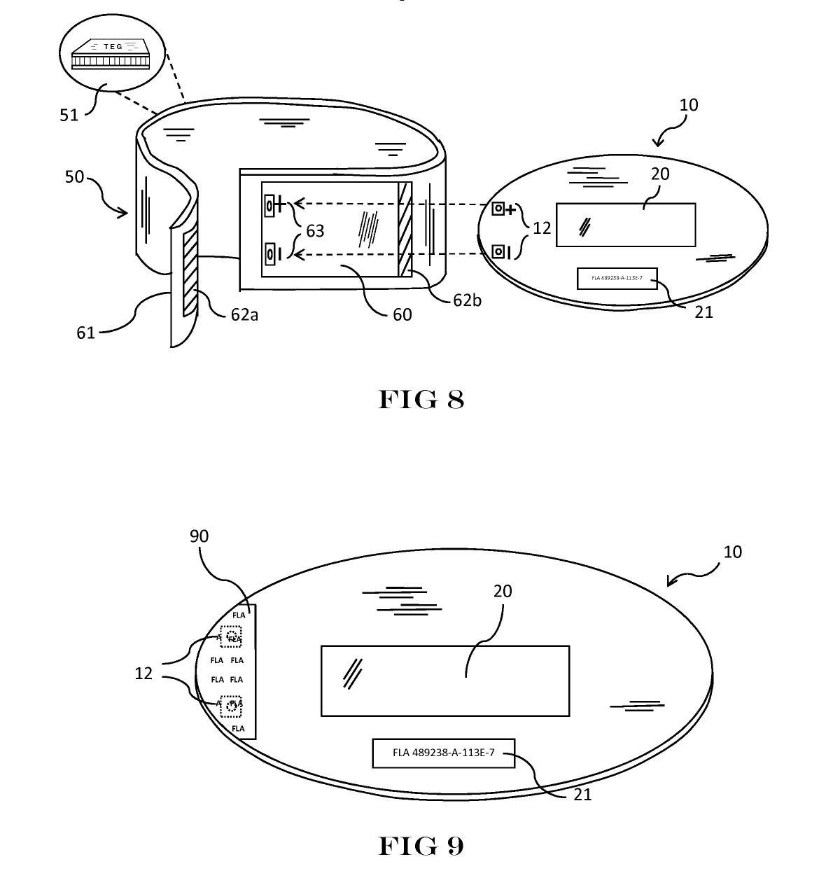

A wristband charging station 50 is this disclosure's proposed solution and is illustrated in FIGS. 5-8. The wristband charging station 50 is similar in material and design to a sweatband that athletes frequently wear. The charging station 50 comprises one or more thermoelectric generators (TEG) 51 capable of harvesting thermal energy from the body heat of a living person or animal and converting it to electrical power. The charging station 50 comprises a charging apparatus 60 covered by a flap 61 that is held in place over the charging apparatus 60 by the two complementing sides of a Velcro strip 62a and 62b. With the flap 61 opened, a powered card 10 can be inserted into the charging apparatus 60, as illustrated in FIG. 8, where the powered card's 10 contact posts 12 make contact with corresponding contact posts 63 disposed inside the charging apparatus 60, electrically connecting the circuitry and components of the powered card 10 with those of the charging apparatus 60. The intended subject of the memorabilia powered card 10, an athlete in this case, then charges the powered card's 10 stacked MEC's 20 by wearing the wristband charging station 50 for a recommended period. It is envisioned that the material of the sweatband charging station 50 covers and protects the one or more TEG's 51, but that the material which covers the one or more TEG's 51 is thin and of a mesh weave so that one planar surface of each of the one or more TEG's 51 is more or less exposed to the wearer's body heat and the other surface of each is essentially exposed to the ambient temperature of the wearer's surroundings. The power output of the one or more TEG's 51 is conditioned by a power management integrated circuit (PMIC) 72, which intervenes to condition the electrical power output of the one or more TEG's 51 and manages the charging of the powered card's 10 stacked MEC's 20.

After the football-shaped powered card 10 has been charged for a sufficient period in this manner, it is removed and, as illustrated in FIG. 9, its contact posts 12 are covered with a nonconductive authentication seal 90 to prevent any subsequent charging of the powered card 10. In alternative designs, the powered card's 10 circuitry could be configured to be broken after the charging step, perhaps by flexing the powered card 10 or by tearing away the contact posts 12, to achieve the same or an enhanced authentication.

While micro-energy cells (MEC) generally require a power management integrated circuit (PMIC) so as to ensure they are not damaged by overdischarging, since the powered card 10 is to be charged only once, damage by overdischarging is not a concern significant enough to warrant the cost of including a PMIC. Thus, there is no PMIC in the powered card's 10 circuitry 30. A manufacturer may decide to include it. The charging station's 50 comprised PMIC 72 fills the role when the powered card 10 is charged.

The powered card 10 is a representative embodiment only. Such a powered card could be of any shape and design appropriate to the person and/or event it is intended to serve as a memorabilia item for, a few examples being: a baseball-shaped powered card for a baseball player, perhaps in a particular game; one shaped like a graduation hat to mark a graduation ceremony; a powered card shaped like a baby to mark the birth of a child; or, in the shape of and/or designed with a military unit's logo to mark a historic military event and the men and women who contributed. Similarly, the manner in which the personal energy is harvested is limited only by practicality. In fact, the powered card 10 could be configured to comprise its own energy harvesting device, such as a thermoelectric, piezoelectric or Faraday generator, for example, in which case there would be no need for a separate charging station, as the powered card 10 could itself be worn or interacted with by the subject to harvest their thermal or kinetic energy. Many copies of this kind of powered card 10 memorabilia could be produced; or, for a very special event, only a few, perhaps only one. If the powered card 10 were additionally configured so that it could output energy through its contact posts 12, it could be used to power a separate electronic device, thereby evincing the subject's harvested energy via that separate device. This separate electronic device and a powered card 10 so configured could be complementing parts of a memorabilia product or a system for delivering a memorabilia experience.

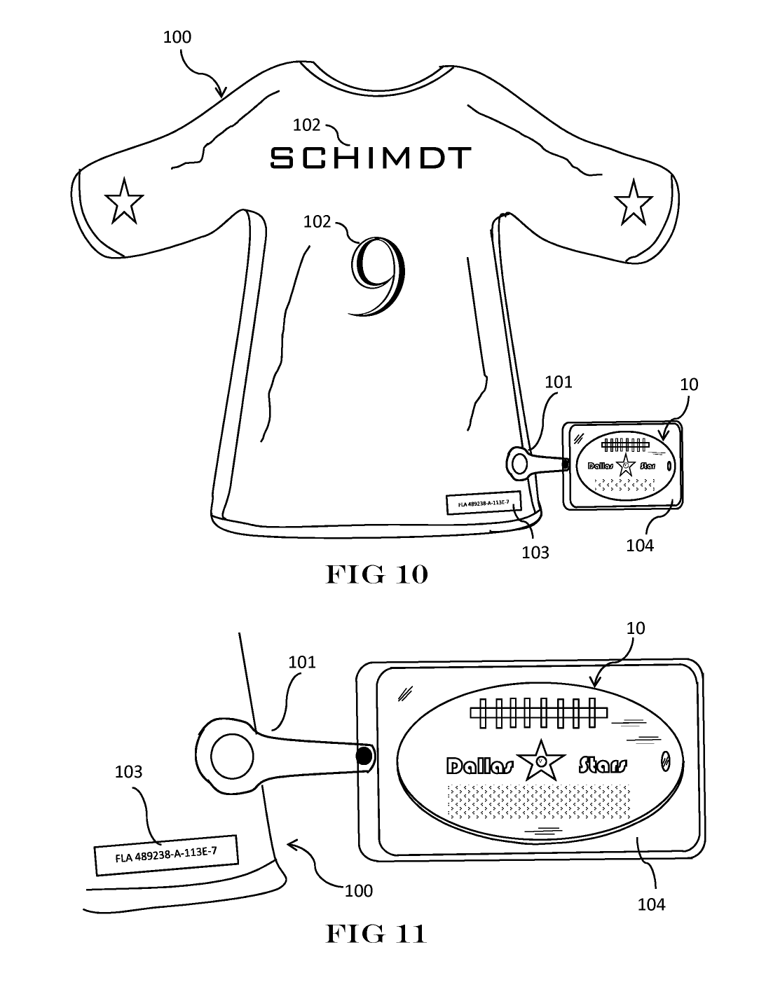

A second representative embodiment has the powered card 10 secured to an American football player's jersey 100, as shown in FIGS. 10 and 11, to create a personal energy memorabilia product by a method that enhances the intrinsic memorabilia worth, and likely the commercial value as well, of an already valued memorabilia item. It is envisioned and preferred that the name and number 102 on the jersey 100 are those of the same player whose harvested personal energy is stored in the powered card 10 of the first embodiment, which, being secured to the jersey 100, is now a part of this second embodiment personal energy memorabilia product. Ideally, the jersey 100 is a so-called “game used” jersey and it was used in a game by the subject player at the same time that they charged the attached powered card 10 with their harvested personal energy.

After being enclosed in a clear plastic pouch 104, the powered card 10 is secured to the jersey 100 by a tether 101. The tether 101 ideally is a tamper-evident type that helps maintain the authenticity of the combined memorabilia product. To further ensure authenticity, a serial number 103 printed on the jersey matches the serial number 21 printed on the back of the powered card 10, as shown in FIG. 2. Further documentation certifying the paired items and perhaps stating under what conditions the jersey 100 was worn and the player's personal energy harvested into the powered card 10 would additionally enhance the product's memorabilia worth, especially if these occurred during a momentous event.

The powered card 10 is intentionally created memorabilia that is made into personal energy memorabilia. The football jersey 100, on the other hand, is incidental memorabilia, i.e. an item that was not created to be a memorabilia item but becomes one because of its association with an event and/or a person of frame and/or significance. The second representative embodiment illustrates how the intrinsic memorabilia worth and possibly the commercial value of such an incidental memorabilia item can be made greater by associating it with a store of harvested personal energy. The same can be achieved by mating a separate intentionally created memorabilia item with a store of harvested personal energy.

Just as the powered card 10 can be of any design and serve as memorabilia to mark any event and person or persons associated with it, the jersey 100, being a representative embodiment only, could be any other item that has come to be valued as an item of memorabilia: a baseball jersey, a tennis player's shirt, a runner's shoes, a famous person's item of clothing, an astronaut's helmet, a part taken from a famous race car, a costume or set item from a movie, an autographed photograph, a pen with which an important document was signed, the collar worn by a famous dog or other animal, a hair brush used on the Kentucky Derby-winning horse, a handkerchief used by a political figure—or any of the many varied types of items that are already commonly valued as memorabilia, incidentally or intentionally occurring. Creative minds will exploit the potential of the personal energy memorabilia genre and the method and devices this second representative embodiment teaches.

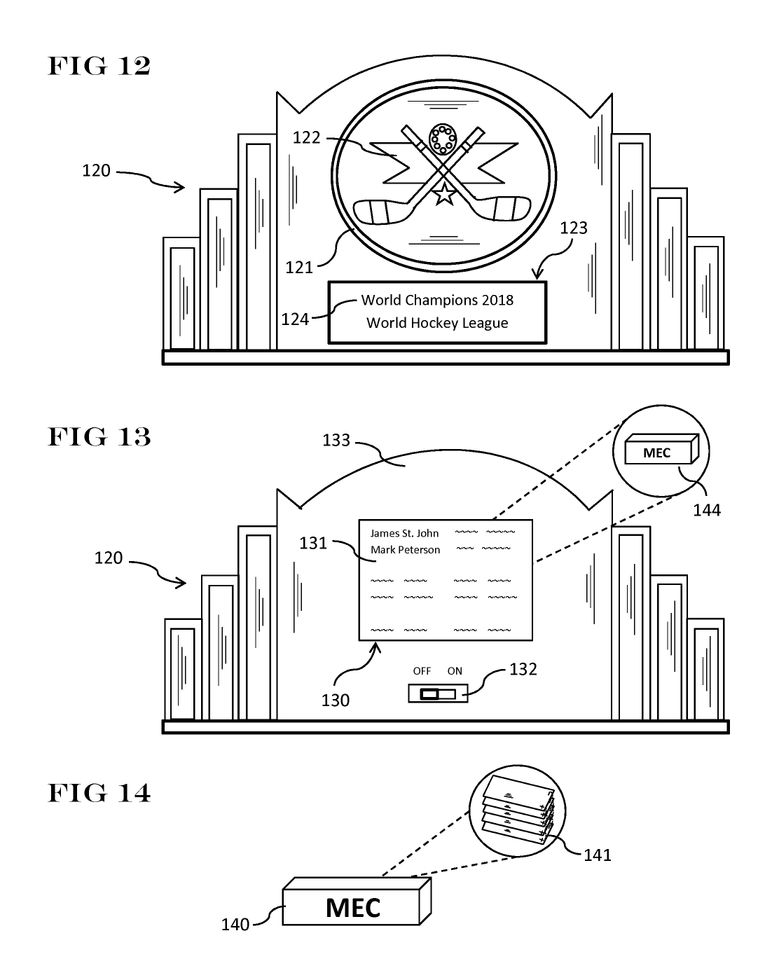

FIGS. 12-14 illustrate a third representative embodiment of a personal energy memorabilia item in the form of an art deco style trophy 120 marking an ice hockey team's league championship. Besides the common metal plate 123 with engraved indicia 124 proclaiming the details of the championship, the front of the trophy 120 features a circular electroluminescent (EL) sheet 121 on which printed artwork 122 depicts the team's logo. The EL sheet 121 is powered by a large number of micro-energy cells (MEC) 141 that are stacked in parallel inside a rechargeable battery pack 140 that is handled and charged outside the trophy 120 before being placed and sealed within the trophy 120 in a finishing step.

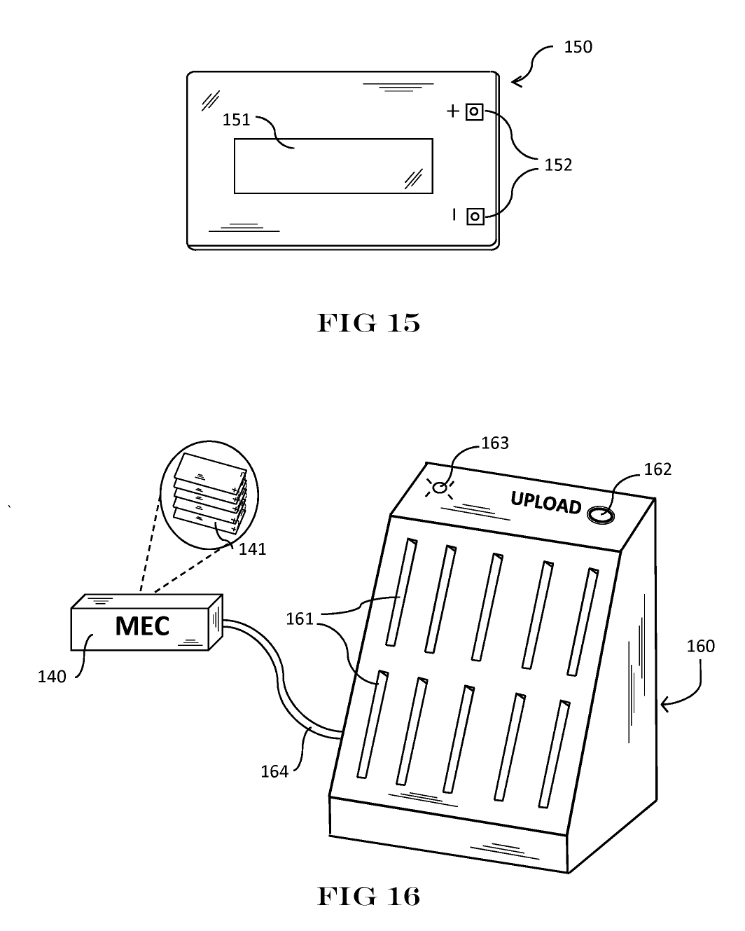

The battery pack 140 is charged with a collective store of personal energy harvested individually from the body of each of the championship team's players. Each team member harvests his individual personal energy; then, the resulting individual stores of the member's individually harvested personal energy are merged to create a single store of the team's collective personal energy in the battery pack's 140 stacked MEC's 141. This is accomplished by having each player wear a wristband charging station 50 of the first representative embodiment, illustrated in FIGS. 5-8, in order to harvest their individual personal energy throughout the match and charge one or more battery cards 150 each. The battery card 150, shown in FIG. 15, is a specially made battery structure of ten stacked MEC's 151 mounted on a celluloid plastic card substrate. A battery card 150, which is outfitted with two contact posts 152, is charged in the same manner as a powered card 10 of the first representative embodiment.

The individually charged battery cards 150 are subsequently collected and the energy stored in each is transferred to the rechargeable battery pack's 140 stacked MEC's 141 by a discharging/charging process in which the personal energy stored in the charged battery cards 150 is used to charge the stacked MEC's 141 that make up the battery pack 140. A specialized discharge/charging station 160 with discharging slots 161 for multiple battery cards 150, such as illustrated in FIG. 16, is proposed. In the discharging/charging process, up to ten charged battery cards 150 at a time are placed in the discharging slots 161; then, a dome switch 162 marked UPLOAD is pressed to start the process of transferring, or “uploading,” the harvested personal energy store of each inserted battery card 150, previously charged as described above, to the stacked battery pack's 140 stacked MEC's 141 via a cable 164. An LED 163 indicates when discharging/charging is taking place; it does this in a manner common to such indicators, perhaps by blinking or remaining lit.

Once all of the team members' individually charged battery cards 150 have been discharged and their energy “uploaded” to the battery pack's 140 stacked MEC's 141, the battery pack 140 is secured inside the trophy 120 and electrically connected to the trophy's 120 internal circuitry to power the trophy's EL sheet 121, which can be selectably operated by a toggle switch 132. It is envisioned that the maker of the trophy 120 at this stage seals the trophy 120 in a tamper-evident way that prevents access to the battery pack 140 so that the battery pack 140 cannot be subsequently recharged or replaced, thus ensuring the authenticity of the store of harvested personal energy residing in the trophy 120.

FIG. 13 illustrates one way this could be accomplished. A metal plate 130, with a list 131 of the team member's names inscribed thereon, covers most of the trophy's 120 rear surface. It is envisioned that access to the battery pack 140 lies behind the metal plate 130, but that the metal plate 130 is adhered to the rear surface 133 in such a way that an attempt to remove or pry it at any point would cause obvious damage to the trophy 120. A tamper-evident authentication seal bordering the metal plate 130 could additionally seal and authenticate the trophy's 120 collective store of harvested personal energy.

The memorabilia trophy card 120 is a representative embodiment only. It represents an approach by which personal energy is harvested external to an item of memorabilia and then caused to be held with, in or on the memorabilia item, where it can be kept long term and optionally used occasionally to power an evincing electronic device. The trophy 120 could be any other item that is valued as memorabilia, and the event, a sports championship in this case, could be any event—or a person or animal—for which memorabilia is created or occurs.

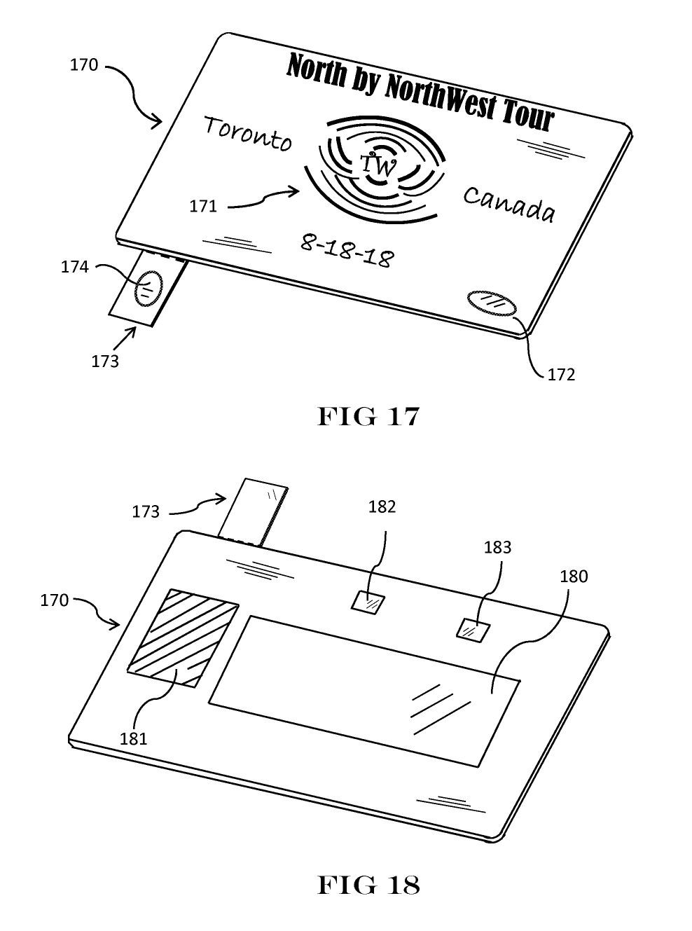

In the previous three embodiments, harvesting of the subject or subjects' personal energy takes place external to the memorabilia item and the harvested personal energy is electrically and/or physically added to the memorabilia item in order to make of it an item of personal energy memorabilia. A fourth representative embodiment demonstrates personal energy memorabilia items that comprise their own energy harvesting capabilities. FIGS. 17 and 18 illustrate a self-charging powered card 170 that serves as a memento of a concert event. The self-charging powered card 170, hereinafter alternately referred to as simply “the card 170,” is a celluloid plastic card of credit card form factor whose main feature is a circular electroluminescent (EL) sheet 171 disposed on the front of the card 170; a rendering the vortex-like logo for a band called “Time Warp”, is printed on the EL sheet 171. Details of the concert—the date, name and location of the tour are printed on the front of the card 170 as well.

The EL sheet 171 is operated by a dome switch 172 and is powered by a stack of five micro-energy cells (MEC) 180 mounted on the back of the card 170. The MEC's 180 are charged by a thermoelectric generator (TEG) 181, which harvests the thermal energy of body heat. A power management integrated circuit (PMIC) 182 intervenes to manage both the charging and discharging of the MEC's 180, and an EL driver 183 conditions voltage for effective illumination of the EL sheet 171 when powered. A concertgoer purchases or otherwise obtains the card 170, likely at the concert venue, and uses it to harvest their own or another concertgoer's personal energy expended during the excitement of the concert, personalizing and making of the card 170 a personal energy memorabilia item.

Because the TEG 181 will harvest energy whenever a temperature difference exists between its hot and cold sides, including the incidental conditions the TEG 181 is exposed to during shipping and handling, there needs to be a way to prevent it from harvesting energy and, more importantly, from charging the MEC's 180 before or after the exact time when a user wants the card 170 to harvest their own personal energy; this would ensure that the MEC's 180 are charged exclusively with the user's personal energy. A detachable tab 173 provides this solution. A second dome switch 174 comprised by the detachable tab 173 controls the flow of electrical power from the TEG 181 to the PMIC 182, which conditions the electrical power to most effectively charge the MEC's 180. The second dome switch 174 is of a type that one hard press noticeably depresses the dome of the dome switch 174 permanently, leaving a clear indentation that lets a user know the harvesting function of the TEG 181 has been initiated.

After pressing the second dome switch 174, a user keeps the card in their clothing or tethered to their body—perhaps in the type of lanyard commonly used to hold and display company identification cards across an employee's chest—so that the TEG 181 will be caused to harvest some of the thermal energy the user's body radiates during the concert. After the concert, or whenever they decide the card 170 has been sufficiently charged, the user tears away the detachable tab 173, thereby permanently disabling the card's 170 harvesting function, which also disables its charging function. Since the card 170 cannot be charged subsequently, it will remain the user's personal energy memento of the concert for as long as the MEC's 180 retain the store of their harvested personal energy, which could be twenty years if the preferred micro-energy cells, stated and described in detail earlier in this disclosure, are used in the card 170. The user can illuminate the EL sheet 171 by pressing the dome switch 172 to see their harvested personal energy evinced. However, to keep the store of their personal energy in the card 170 long term, the user should only occasionally and briefly turn on the EL sheet 171.

The concert memorabilia self-charging powered card 170 is a only representative embodiment of the present invention. It demonstrates that a personal energy memorabilia item can comprise all the components and circuitry necessary to harvest, convert to electrical power, store and use the personal energy of a person and/or animal. Such a self-charging powered card 170 could be created as memorabilia for any significant event—cultural, historical, or personal. Another item could serve the same role as the disclosed self-charging powered card 170: for example, an item of jewelry, a stuffed animal toy, a hat, a cup, a pair of shoes, etc.—anything that could be similarly outfitted. Another method and/or device could be used to harvest the concertgoer's personal energy, such as a piezoelectric, biomechanical, or Faraday device; a thermoelectric generator is employed by this representative embodiment simply because body heat is the inventor's preferred source of personal energy for a personal energy memorabilia item.

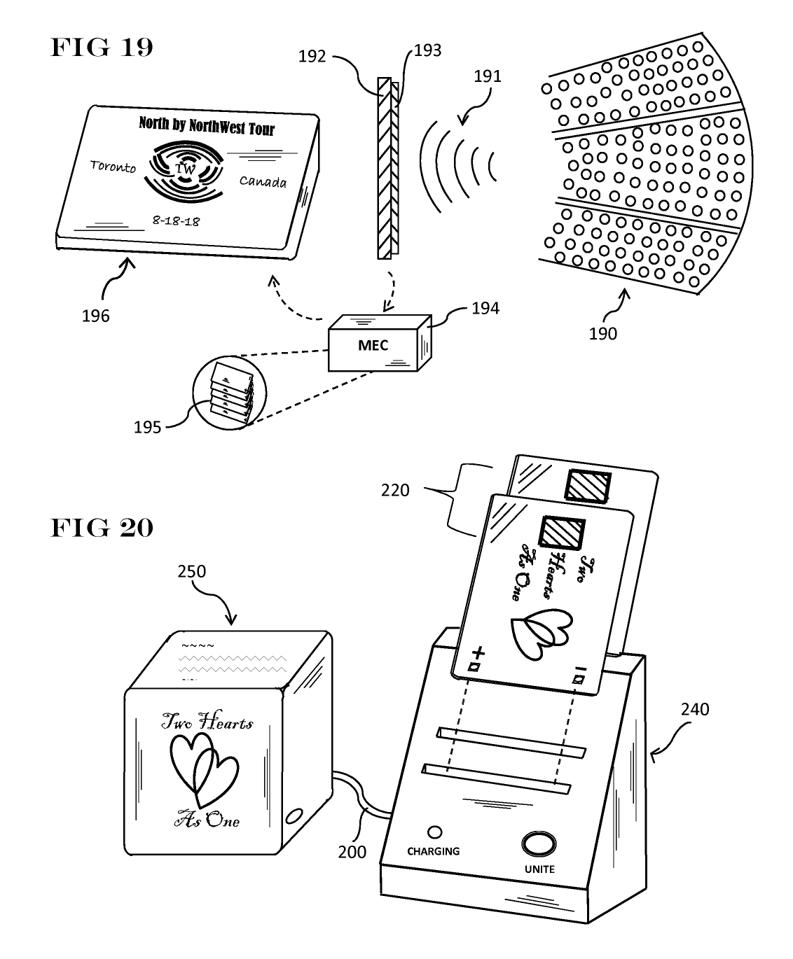

FIG. 19 illustrates a fifth representative embodiment of the method disclosed by the present invention wherein the collective personal energy of a crowd 190 is harvested. So-called “crowd noise” generates a type of energy referred to as acoustic energy 191, which can be harvested by specialized piezoelectric generator modules. Because this acoustic energy 191 is generated by people expending energy from their bodies—voicing, clapping, stomping, etc.—the energy is “personal energy” as defined earlier in this disclosure. In this embodiment, the collective acoustic energy 191 of the crowd noise is harvested by a harvesting panel 192 lined with an array of a large number of piezoelectric generators (PEG's) 193 which are capable of harvesting the acoustic energy 191 of crowd noise. As the crowd's 190 acoustic energy 191 impacts the harvesting panel 192, the PEG's 193 collect and convert the acoustic energy 191 to electrical power, which it outputs to a rechargeable battery pack 194, to charge a large number of stacked MEC's 195 with the crowd's 190 harvested and converted personal energy. Later, the energy stored in the battery pack 194 is transferred to a limited edition memorabilia plaque 196 that marks the concert event, either by installing the battery pack 194 into the plaque 196 or by using the charged battery pack's 194 stored energy to charge separate energy storage devices (preferably also MEC's) comprised in the plaque 196.

To eliminate the harvesting of other acoustic energy, such as that coming from the band's musical instruments and audio amplifiers, the piezoelectric generators 193 could be tuned to a frequency or pattern of acoustic energy 191 typical of crowd noise. Or, the crowd's collective acoustic energy 191 could be harvested “on cue”, wherein the audience is told about the harvesting project and at certain times throughout the concert asked to “make as much noise as you can” for the project. It is envisioned that the memorabilia plaque 196 is used as a promotional item, perhaps to promote the band itself or to raise funds for a cause supported by the band and its fans; perhaps given away to the holder of a selected ticket number, or auctioned to the highest bidder in another venue, such as an online auction. Depending on the size of the crowd 190, the total amount of crowd noise/acoustic energy 191 they generate, and the efficiency of the PEG panel 192, more than one of this special memorabilia plaque 196 could be produced.

Together, the conditions (a concert event) and the product (a memorabilia plaque 196) described here form only a representative alternative embodiment of the present invention's method. Wherever a crowd of people—or animals—gathers and creates or can create a significant amount of crowd noise, their acoustic energy, which is a collective evincement of personal energy, could be harvested in the same or other ways. And, any other imaginable item besides the memorabilia plaque 196 proposed here could be associated with that harvested collective personal energy to create a personal energy memorabilia item. Further, other methods and/or devices, alone or in combination, for harvesting a crowd's collective personal energy could be employed, such as, but not limited to, harvesting the vibration of a building or other structure caused by the crowd moving within or on it; or harvesting the collective thermal heat that accumulates along the ceiling or roof of an enclosed area occupied by a crowd, human or animal.

The representative embodiments presented thus far have been related to public events and persons. A sixth representative embodiment of the present invention demonstrates that personal energy memorabilia can be created for personal events, individuals or a small group as well. FIG. 20 illustrates a method and concomitant devices for creating a personal energy wedding keepsake, an illuminated cube 250 that is personalized and thus enhanced with the combined harvested personal energy of a newlywed couple and features an electroluminescent (EL) sheet 253 disposed on the cube's 250 front surface 254 and cut in the shape of two hearts merging.

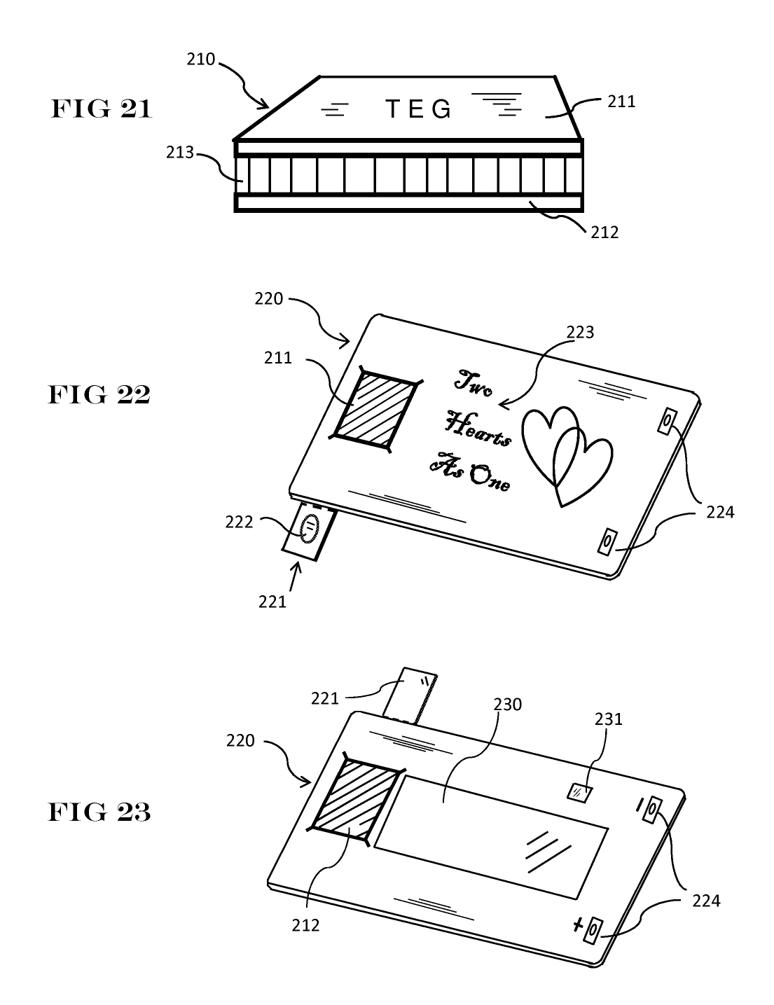

FIGS. 22 and 23 illustrate a self-charging battery card 220, seen in FIG. 20 as well, The battery card 220 comprises a thermoelectric generator (TEG) 210, shown in detail in FIG. 21. Thermoelectric generators exploit the Seebeck effect, a phenomenon by which an electric current is produced when there exists a temperature differences between two dissimilar metals in a circuit; in short, thermal energy is converted to electrical power. Thus, the TEG 210 has two planar surfaces, a “hot side” 211 and a “cold side” 212, which sandwich a large number of thermopiles 213. The TEG 210 is mounted in the body of the battery card 220 such that its hot side 211 is exposed at the front of the battery card 220, while its cold side 212 is exposed at the rear. The TEG 210 used in this embodiment is specialized to harvesting thermal energy from the warm body of a person or animal, which it converts and outputs as electrical power to charge a stack of five micro-energy cells (MEC) 230 via an intervening power management integrated circuit (PMIC) 231, both mounted on the back of the battery card 220. The front surface of the battery card has artwork and indicia 223 related to a wedding day.

Because the TEG 210 will harvest energy whenever there exists a temperature difference between its hot side 211 and cold side 212, there needs to be a way to prevent it from charging the MEC's 230 with electrical power resulting from the TEG's 210 exposure to ambient, incidental thermal energy at any time other than the exact time that the couple wants to harvest their individual personal energy. As with the fourth embodiment, a detachable tab 221 provides this solution. A dome switch 222 disposed on the detachable tab 221 controls by circuitry the flow of electrical power from the TEG 210 to the stacked MEC's 230 via the previously identified (PMIC) 231. The dome switch 222 is of a type that one hard press noticeably depresses the dome permanently, leaving a clear indentation in it that thereby lets a user know the battery card's 220 harvesting and charging functions have been initiated.

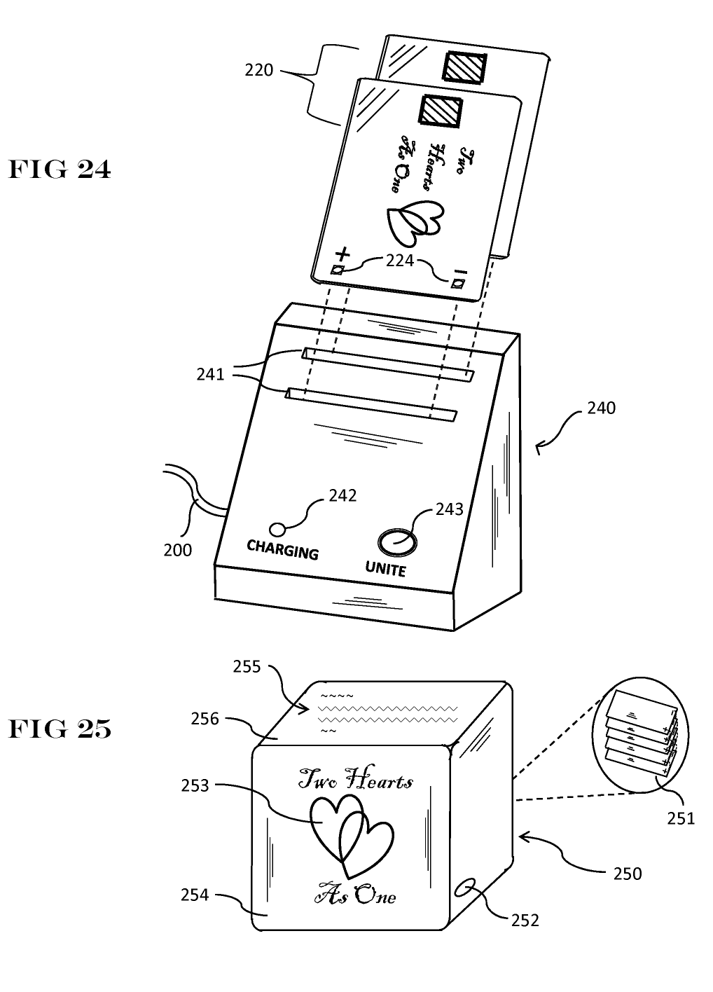

Throughout the wedding day, the bride and groom each keep close to their bodies one or more of the battery cards 220 (after having pressed the dome switch 222 on each battery card 220) to harvest and create separate stores of their individual personal energy. Later, the bride and groom each insert one of their individually charged battery cards 220 into one of the two discharging slots 241 of a customized discharging/charging station 240, seen in FIG. 20 and shown in detail in FIG. 24, where the battery card's 220 two contact posts 224 make contact with the discharging/charging station's 240 circuitry (not shown). A cable 200 electrically connects the discharging/charging station 240 to the illuminated cube 250.

The couple then presses a button switch 243 on the discharging/charging station 240 that is marked “UNITE.” An LED 242, marked “CHARGING,” blinks to indicate the start of a process by which the discharging/charging station 240 uses the electrical power stored in the couple's individually charged battery cards 220 to charge a large number of stacked micro-energy cells (MEC) 251 comprised in the cube 250. In this manner, the two separate stores of the bride and groom's individually harvested personal energy are transferred and merged to become one in the wedding keepsake illuminated cube 250. The couple repeats this step until all the battery cards 220 that they individually charged on the wedding day have been similarly processed. The couple could decide to extend the period of harvesting, perhaps through their honeymoon, to yield a greater store of their combined personal energy in their wedding keepsake cube 250.

Finally, the couple can experience their merged personal energy evinced through the EL sheet 253 by pressing a dome switch 252 to turn it on or off. The EL sheet 253 has wedding themed artwork, two hearts merging, printed on it. Indicia 255 disposed on the top surface 256 could have the couple's names, the details of their wedding day and perhaps a poem, a prayer, or a printed version of their marriage vows. Because of the exceptional charged shelf life of the preferred micro-energy cells (MEC) 251, the store of the couple's combined personal energy could reside in their illuminated cube 250 wedding keepsake for decades, a shelf-life depending on how many MEC's 251 are used, how much personal energy the couple harvests and adds to the MEC's 251, and how much the couple uses their merged personal energy stored in the MEC's 251 to illuminate the EL sheet 253.

The method for creating this particular personal energy wedding keepsake involves a number of intervening pieces of equipment. It is envisioned that wedding planning service providers may offer some of this equipment for rent. For instance, a couple could purchase from the wedding planner a keepsake such as the illuminated cube 250 and then rent re-usable versions of the proposed battery cards 220 as well as the discharge/upload station 240. (If re-usable, the circuitry of the battery cards 220 should include a PMIC.)

Just as with the previously disclosed representative embodiments, the wedding keepsake illuminated cube 250 is only a representative embodiment of the present invention. It demonstrates how personally relevant memorabilia, often referred to as keepsakes, can be enhanced with a person's—and/or animal's—harvested personal energy just the same as cultural and historical memorabilia can. Any other item capable of being similarly outfitted and treated could serve the same memorabilia role as the cube 250.

Moreover, an item of the wedding keepsake illuminated cube 250 kind could be created for any personally significant event: a class graduation, wherein members of the class “merge” their personal energy in one or more keepsake items; the birth of a child, wherein the energy of the child alone or that of the newborn and his mother and/or father are added; a group of friends or colleagues who want to mark a shared experience. The envisioned renting scheme described above would apply to any of these as well if a similar system were employed, (and would also be a convenient service to provide with the team trophy 120 of the third embodiment). In an alternative approach, a similar wedding keepsake could additionally or alternatively comprise a storage area where a number of powered card similar to those of the first and fourth representative embodiments could be kept after being charged in the same or a similar method just described.

To be truly an item of personal energy memorabilia, the energy stored in the item's comprised or accessory energy storage device that serves as the repository of the subject's personal energy needs to be as purely and exclusively a store of the subject's harvested personal energy as possible. Most mass produced batteries are delivered from a manufacturer fully charged with energy produced by the manufacturer or its local utility. Thus, they need to be fully discharged at some point before the subject's personal energy is harvested. Ideally, the provider of a personal energy memorabilia product or the provider of the above-mentioned “battery cards”—or similarly purposed batteries—would fully discharge the energy storage devices used in or with their products before providing them.

However, if pre-charged energy storage devices are provided to end users, then the users will need to fully discharge the energy storage devices of their “factory charge” in a preparatory step to harvesting the subject's personal energy. If the latter is the case, and the preferred micro-energy cells (MEC) are the energy storage devices used, then a power management integrated circuit (PMIC) needs to be included in the circuitry of the “battery card” or other energy storage structure built with MEC's. This discharging preparatory step could be accomplished by a device similar to the above described charging or discharging stations (e.g. the wristband charging station 50, the discharge/charging station 160, the discharge/charging station 240). Or, it could be accomplished by using the energy storage device to power an electronic device, comprised in or external to the product, until the former is fully “drained” of its factory charge.

In specifying the six representative embodiments above, certain charging methods and devices, such as the wristband charging station 50 and its thermoelectric generator 70, are described. Other methods and devices can be employed, imagination and practicality the only limits. The subject of a personal energy memorabilia item can harvest their own personal energy firsthand, or their personal energy could be harvested secondhand, i.e. by a person who is not the subject. For instance, if the subject were a child, an incapacitated person, or an animal, then secondhand harvesting would likely be more practical. Also, the place or area of the body from which personal energy is harvested can be left to a user to decide. There could be areas of the body that are aesthetically, emotionally, or otherwise relevant to the subject of the personal energy memorabilia item and/or the event they are associated with that could influence harvesting site preferences.

Preferably, a personal energy memorabilia product will comprise or have as an accessory an item that comprises at least one electronic device that is powered by an energy storage device which has been charged with the harvested personal energy of the item's subject. A personal energy memorabilia item that comprises and/or has accessory to it more than one electronic device could have all of the devices powered by a single or multiple stores of the subject's harvested personal energy; or, one or more of the electronic devices could be powered by the harvested personal energy while another or other electronic devices are powered by one or more separate, conventionally charged electrical energy storage devices. For example, a personal energy memorabilia item could comprise an electronic device that produces an audio output and another that features an LED light display. While a battery that is charged with the subject's harvested personal energy could power the LED light, an off-the-shelf battery that's been charged conventionally could power the audio component. This arrangement would yield a hybrid personal energy memorabilia item.

Moreover, the types of output of any such evincing electronic device(s) are limited only by this invention's requirement that the output evince stored harvested personal energy by directly or indirectly stimulating one or more human senses; light, heat, sound, vibration, electrical shock, a scent, animated movement, for example but not limited to, would all fulfill the requirement. It is possible, however, that a personal energy memorabilia item could also comprise or be associated with a store of harvested personal energy alone; the item need not comprise nor be part of a system that comprises an electronic device. Some memorabilia collectors may value merely having a store of the subject's harvested personal energy and not care to have it evinced through electronics.

In collective personal energy memorabilia arrangements, a single comprised or accessory energy storage device could hold the merged harvested personal energy of two or more people and/or animals and power a single or several comprised or accessory electronic devices. Alternatively, a collective personal energy memorabilia item could comprise or have as accessory a number of individual energy storage devices, one or more for each person and/or animal subject of the memorabilia item, which together power one or more electronic devices or individually power dedicated electronic devices; or, which power a number of electronic devices in one or more of these arrangements. The individual personal energy harvested for a collective personal energy memorabilia item could be harvested in a single process wherein all of the subjects of the collective memorabilia item have their personal energy harvested in the same process at the same time; it could be harvested in the same process but at different times; or, it could be harvested in different processes at the same or different times.

For each of the six representative embodiments described above the subject of the memorabilia item created is a person or group of people, and animal subjects are mentioned as possible. Certain animals gain significance in human culture as celebrities; for example, framed zoo animals, or animals featured in movies, television or news stories. A racehorse that wins one or more of the “triple crown” races is just as much a celebrity to horseracing fans as any human athlete, and energy harvested from its body heat and motion during such a big race would be precious. There exists memorabilia for such animals and that memorabilia can be enhanced or intentionally created as personal energy memorabilia in ways similar to or the same as the methods and embodiments laid out in the above six representative embodiments specifics.

On a personal level, owners of pets may wish to create personal energy memorabilia that are associated with a store or stores of the pets' individual or collective harvested personal energy. Collective personal energy memorabilia could be created for two or more animal subjects just as with human subjects. Furthermore, collective personal energy memorabilia could have both human and animal subjects, with their personal energy stored and possibly evinced electronically in one or more of the collective arrangements described above.

Representative embodiments of the present invention have been shown, and preferences and guidance for creating the same have been given, all with the aim of providing information that can help those skilled in the relevant arts actualize the concept and teachings of the present invention. With the aforementioned depictions serving to represent and exemplify, it will be appreciated by those skilled in the art that these depictions are made by way of example only, that the invention is not limited to the particular embodiments described in this disclosure, and that various adaptations, changes, configurations, and substitutions may be made in any practical application of the present invention without departing from the principles and spirit of the representative embodiments nor the scope of the invention as hereinafter claimed.

What is claimed is:

1. A method for enhancing a memorabilia item, the method comprising:
associating a memorabilia item with an energy storage device that has been charged directly or indirectly with electrical power generated by an energy harvesting device, wherein said energy harvesting device generates said power by harvesting energy from the living body or bodies of one or more persons and/or animals and converting said energy to said power.

2. The method of claim 1, wherein the memorabilia item derives its intrinsic memorabilia worth and usefulness:
from its separate and independent association with an event and/or its separate and independent association with one or more persons and/or animals; and
by serving as a record or reminder of said event and/or said one or more persons and/or animals.

3. The method of claim 1, wherein the one or more persons and/or animals from whom energy is harvested:
are the same one or more persons and/or animals which the memorabilia item is separately and independently associated with; and/or
are associated with the same said event that the memorabilia item is separately and independently associated with.

4. The method of claim 1, wherein the memorabilia item comprises the energy storage device.

5. The method of claim 1, wherein the energy storage device is separate and external to the memorabilia item.

6. The method of claim 5, wherein the energy storage device is a standalone unit or is comprised in another object.

7. The method of claim 6, wherein the memorabilia item comprises an electronic device that can be powered by the said energy storage device.

8. The method of claim 6, wherein the said energy storage device is secured to or with the memorabilia item in any suitable manner.

9. The method of claim 6, wherein the said energy storage device is packaged with the memorabilia item in any suitable manner.

10. The method of claim 6, wherein the said energy storage device and the memorabilia item are parts of a memorabilia product or system.

11. The method of claim 6, wherein the object is accessory to the memorabilia item.

12. A method for enhancing a memorabilia item, the method comprising:
providing a memorabilia item, the memorabilia item comprising:
at least one electronic device capable of producing an output that stimulates one or more of the five human senses; and
at least one chargeable electrical energy storage device, said device electrically and operably connected to the said at least one electronic device; and
electrical circuitry for selectably powering the at least one electronic device with the at least one chargeable electrical energy storage device; and
design elements, artwork and/or indicia that serve to associate the memorabilia item with an event and/or one or more persons and/or animals; and
directly or indirectly charging the at least one chargeable electrical energy storage device with electrical power generated by an energy harvesting device, wherein the energy harvesting device generates said electrical power by harvesting energy from the living body or bodies of one or more persons and/or animals and converting said energy to said electrical power.

13. The method of claim 12, wherein the one or more persons and/or animals from whom energy is harvested in the last step:
are the same one or more persons and/or animals associated with the memorabilia item; and/or
are in some way related to the event associated with the memorabilia item.

14. The method of claim 12, wherein one or more of the steps are accomplished by one party or certain parties while the other step or steps are accomplished by another party or other parties; or wherein all of the steps are accomplished by one party alone.

15. A method for enhancing a memorabilia item, the method comprising:
providing a memorabilia item, the memorabilia item comprising:
at least one electronic device capable of producing an output that stimulates one or more of the five human senses; and
electrical circuitry for connecting with and selectably powering the at least one electronic device with at least one chargeable electrical energy storage device; and
design elements, artwork and/or indicia that serve to associate the memorabilia item with an event and/or to associate the memorabilia item with one or more persons and/or animals; and
charging an electrical energy storage device with electrical power generated by an energy harvesting device, wherein the energy harvesting device generates said electrical power by harvesting energy from the living body or bodies of one or more persons and/or animals and converting said energy to said electrical power; and
electrically connecting said electrical energy storage device with the said electronic device.

16. The method of claim 15, wherein the one or more persons and/or animals from whom the said energy is harvested:
are the same one or more persons and/or animals associated with the memorabilia item; and/or
are in some way related to the event associated with the memorabilia item.

17. The method of claim 15, wherein one or more of the steps are accomplished by one party or certain parties while other of the steps are accomplished by another party or other parties; or wherein all of the steps are accomplished by one party alone.

18. A method for enhancing a memorabilia item, the method comprising:
providing a memorabilia item, the memorabilia item comprising design elements, artwork and/or indicia that serve to associate the memorabilia item with an event and/or to associate the memorabilia item with one or more persons and/or animals; and
charging an electrical energy storage device with electrical power generated by an energy harvesting device, wherein the energy harvesting device generates said electrical power by harvesting energy from the living body or bodies of one or more persons and/or animals and converting said energy to said electrical power; and
securing the said electrical energy storage device with the memorabilia item by any suitable manner.

19. The method of claim 18, wherein the one or more persons and/or animals from whom energy is harvested:
are the same one or more persons and/or animals associated with the memorabilia item; or
are in some way linked to the event associated with the memorabilia item.

20. The method of claim 18, wherein one or more of the steps are accomplished by one party or certain parties while other of the steps are accomplished by another or other parties; or, wherein all of the steps are accomplished by one party alone.
